(19) United States
(12) Patent Application Publication
(10) Pub. No.: US 2016/0056285 A1
(43) Pub. Date: Feb. 25, 2016

(54) HIGH-VOLTAGE METAL-OXIDE-SEMICONDUCTOR TRANSISTOR DEVICE WITH INCREASED CUTOFF FREQUENCY

(71) Applicant: MEDIATEK INC., Hsin-Chu (TW)

(72) Inventor: Puo-Yu Chiang, Yilan County (TW)

(21) Appl. No.: 14/467,054

(22) Filed: Aug. 25, 2014

(51) Int. Cl. H01L 29/78; H01L 29/10

(52) U.S. Cl. CPC H01L 29/7835; H01L 29/1041

(57) ABSTRACT

A HVMOS transistor structure includes a semiconductor substrate; a gate overlying the semiconductor substrate; a gate dielectric layer between the gate and the semiconductor substrate; a sidewall spacer on each sidewall of the gate; a drain structure in the semiconductor substrate on one side of the gate; an ion well of the first conductivity type in the semiconductor substrate; a source structure in the semiconductor substrate being space apart from the drain structure; and a channel region between the drain structure and the source structure, wherein the channel region substantially consisting of two gate-overlapping regions of the first conductivity type having doping concentrations different from each other.

### BACKGROUND

The invention relates generally to the field of power semiconductor transistor devices. More particularly, the invention relates to a high-voltage metal-oxide-semiconductor (HVMOS) transistor device having an increased cutoff frequency (Ft).

High-efficiency power semiconductor transistors integrated on a silicon substrate, e.g. drain-extension MOS transistors for radio frequency power applications, are widely employed in such portable devices as mobile phones.

Typically, high-voltage MOS devices have a limited cutoff frequency. However, there are some applications where a high cutoff frequency is requested, as for example in telecommunications and especially in wireless appliances. To maximize the cutoff frequency Fₜ, it is necessary to minimize the effective gate channel length (L_{g, eff}).

It is well known that the threshold voltage (Vt) of a MOS transistor drops with decreasing L_{g, eff}. When Vt drops too much, off-state leakage current (I_{off}) becomes too large and that channel length is not acceptable. The Vt roll-off phenomenon may become more pronounced as respective channel lengths are decreased.

Traditional HVMOS devices utilize well to poly photo alignment to control device channel length. However, it suffers from poor process control and worse Vt roll-off, which limit the minimum L_{g, eff} to about 0.6 micrometers, and therefore a higher cutoff frequency cannot be achieved.

### SUMMARY

It is one object of the invention to provide an improved high-voltage metal-oxide-semiconductor (HVMOS) transistor structure that has an increased cutoff frequency (Ft) and is compatible with current CMOS processes.

According to one aspect of the invention, a HVMOS transistor structure includes a semiconductor substrate; a gate overlying the semiconductor substrate; a gate dielectric layer between the gate and the semiconductor substrate; a sidewall spacer on each sidewall of the gate; a drain structure in the semiconductor substrate on one side of the gate; an ion well of the first conductivity type in the semiconductor substrate; a source structure in the semiconductor substrate being space apart from the drain structure; and a channel region between the drain structure and the source structure, wherein the channel region substantially consisting of two gate-overlapping regions of the first conductivity type having doping concentrations different from each other.

According to another aspect of the invention, a HVMOS transistor structure includes a semiconductor substrate having a first conductivity type; a gate overlying the semiconductor substrate; a gate dielectric layer between the gate and the semiconductor substrate; a sidewall spacer on each sidewall of the gate; a drain structure in the semiconductor substrate on one side of the gate, wherein the drain structure comprises a drift region of a second conductivity type extending below the gate to partially overlap with the gate, and a drain contact region of the second conductivity type in the drift region; an ion well of the first conductivity type in the semiconductor substrate and being situated adjacent to the drift region, wherein the ion well has a first doping concentration; a source structure in the semiconductor substrate on the other side of the gate opposite to the drain structure, wherein the source structure comprises a shallow ion well of the first conductivity type in the ion well, a source contact region of the second conductivity type in the shallow ion well, and a lightly doped drain (LDD) region within the shallow ion well and directly underneath the spacer, and wherein the shallow ion well extends below the gate to partially overlap with the gate and has a second doping concentration, wherein the second doping concentration is higher than the first doping concentration; and a channel region substantially consisting of an overlapping region between the shallow ion well and the gate, and an overlapping region between the ion well and the gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic sectional view diagram showing an exemplary HVMOS transistor structure according to one embodiment of the invention;

FIG. 2 is a schematic sectional view diagram showing an HVMOS transistor structure according to another embodiment of the invention; and

FIG. 3 is a schematic sectional view diagram showing an HVMOS transistor structure according to yet another embodiment of the invention.

It should be noted that all the figures are diagrammatic. Relative dimensions and proportions of parts of the drawings are exaggerated or reduced in size, for the sake of clarity and convenience. The same reference signs are generally used to refer to corresponding or similar features in modified and different embodiments.

### DETAILED DESCRIPTION

One or more implementations of the present invention will now be described with reference to the attached drawings, wherein like reference numerals are used to refer to like elements throughout, and wherein the illustrated structures are not necessarily drawn to scale.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Throughout the specification and drawings, the term “gate length” or “L_{g}”, unless otherwise specified, refers to the physical length of the gate or polysilicon gate of a transistor in a source to drain direction, which can normally be accurately measured with a scanning electron microscope (SEM).

The term “gate channel region”, “gate channel” or “channel” refers to the silicon region or inversion layer between the source and drain regions underneath the gate, which could be P type or N type when the device is turned on. The gate channel length usually differs from the gate length by an amount depending on the gate lithography and the etch bias, as well as on the lateral source/drain diffusion. The term “effective gate channel length” or “L_{g, eff}”refers to the length or dimension of the effective gate channel region between the source and drain regions underneath the gate, which actually determines the turn-on or turn-off status of the transistor device.

The terms “wafer” or “substrate” used herein includes any structure having an exposed surface onto which a layer is deposited according to the present invention, for example, to form the integrated circuit (IC) structure. The term “substrate” is understood to include semiconductor wafers. The term “substrate” is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art.

The term “horizontal” as used herein is defined as a plane parallel to the conventional major plane or surface of the semiconductor chip or die substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “over”, and “under”, when used, are defined with respect to the horizontal plane.

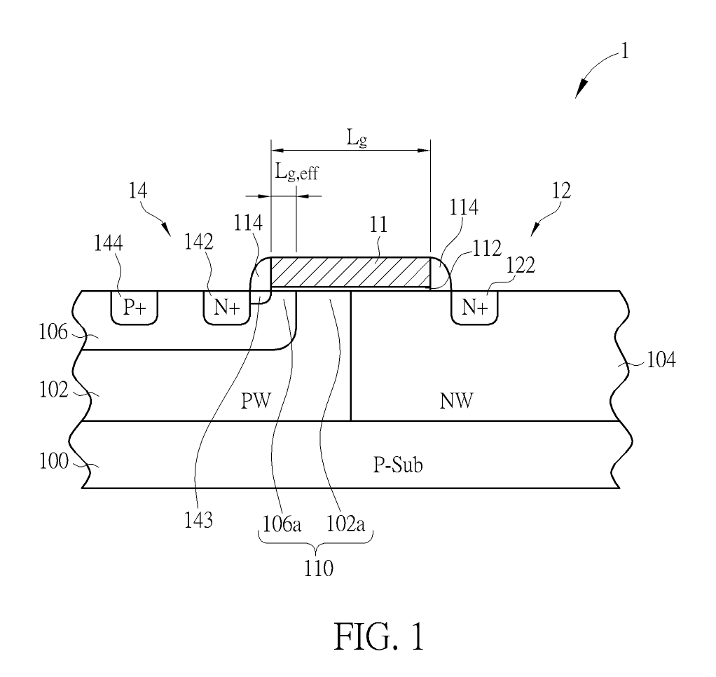

FIG. 1 is a schematic sectional view diagram showing an exemplary HVMOS transistor structure according to one embodiment of the invention. As shown in FIG. 1, the HVMOS transistor structure 1 comprises a semiconductor substrate 100 such as a P type silicon substrate (P-Sub). A gate 11 is disposed on a major surface of semiconductor substrate 100. The gate 11 may comprise at least one conductive layer such as doped polysilicon, metal, or metal silicide. A gate dielectric layer 112 such as a silicon dioxide layer may be disposed between the gate 11 and the semiconductor substrate 100. On the opposite sidewalls of the gate 11, a pair of sidewall spacers 114 is provided. The sidewall spacers 114 may be composed of silicon oxide, silicon nitride, or silicon oxynitride. The gate 11 has a gate length L_{g} that may range between 0.2 micrometers and 0.6 micrometers, for example, 0.48 micrometers.

The HVMOS transistor structure 1 further comprises a drain structure 12 in the semiconductor substrate 100. According to the embodiment, the drain structure 12 comprises an N type drift region 104 or N well (NW). The N type drift region 104 extends below the gate to partially overlap with the gate 11. The drain structure 12 further comprises an N⁺ contact region 122 formed in the N type drift region 104. The N⁺ drain contact region 122 is disposed adjacent to an edge of the one of the sidewall spacers 114. It is noteworthy that no lightly doped drain (LDD) is provided within the N type drift region 104 underneath the sidewall spacer 114 according to the embodiment.

A P well (PW) 102 is provided in the semiconductor substrate 100 and is situated adjacent to the N type drift region 104. According to the embodiment, the P well 102 has a first doping concentration. For example, the first doping concentration may range between 1e15 atoms/com³ and 1e16 atoms/cm³. According to the embodiment, the first doping concentration of the P well 102 is higher than the doping concentration of the semiconductor substrate 100. According to the embodiment, the P well 102 is contiguous with the N type drift region 104, and the P well 102 partially overlaps with the gate 11.

The HVMOS transistor structure 1 further comprises a source structure 14 in the semiconductor substrate 100. According to the embodiment, the source structure 14 comprises a shallow P well 106 in the P well 102. According to the embodiment, the shallow P well 106 has a second doping concentration. For example, the second doping concentration may range between 1e15 atoms/com³ and 5e16 atoms/cm³. According to the embodiment, the second doping concentration is higher than the first doping concentration. According to the embodiment, the shallow P well 106 also partially overlaps with the gate 11. The overlapping region 106a of the shallow P well 106 and the overlapping region 102a of the P well 102 constitute a channel region 110.

It is one germane feature of the invention that the channel region 110 of the HVMOS transistor structure 1 substantially consists of two P type gate-overlapping regions 106a and 102a having doping concentrations different from each other, wherein the overlapping region 106a that is closer to the source structure 14 has a higher doping concentration than the overlapping region 102a that is closer to the drain structure 12. The effective gate channel length (L_{g, eff}) is defined as the length or dimension of the overlapping region 106a in a gate lengthwise direction. The shallow P well 106 may be formed by using a self-aligned ion implantation method, and therefore the effective gate channel length (L_{g, eff}) can be very small, thereby increasing the cutoff frequency (Ft).

The source structure 14 further comprises an N⁺ source contact region 142 formed in the shallow P well 106. Likewise, the N⁺ source contact region 142 is disposed adjacent to an edge of the one of the sidewall spacers 114. An N type lightly doped drain (NLDD) region 143 is provided directly underneath the spacer 114 and is merged with the N⁺ source contact region 142. Further, a P⁺ well pick-up region 144 may be formed within the shallow P well 106.

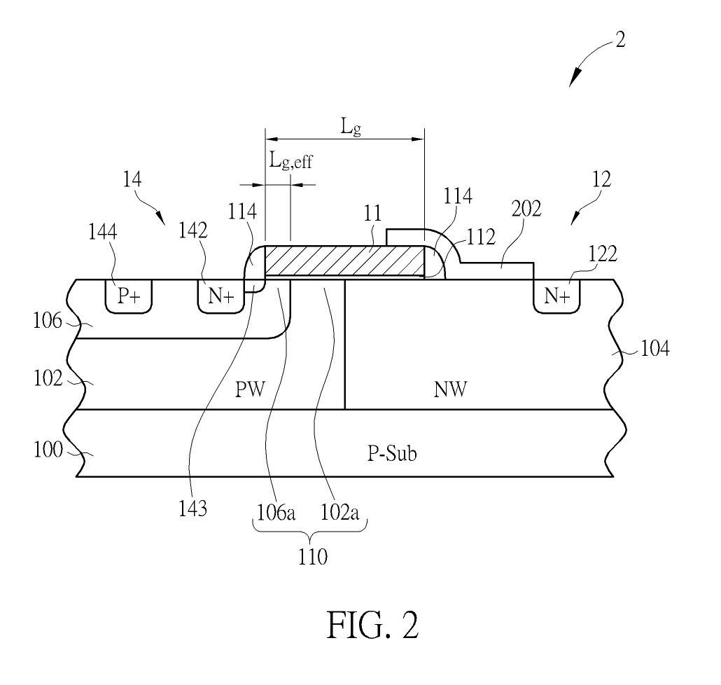

FIG. 2 is a schematic sectional view diagram showing an HVMOS transistor structure according to another embodiment of the invention. As shown in FIG. 2, likewise, the HVMOS transistor structure 2 comprises a semiconductor substrate 100 such as a P type silicon substrate. A gate 11 is disposed on a major surface of semiconductor substrate 100. The gate 11 may comprise at least one conductive layer such as doped polysilicon, metal, or metal silicide. A gate dielectric layer 112 such as a silicon dioxide layer may be disposed between the gate 11 and the semiconductor substrate 100. On the opposite sidewalls of the gate 11, a pair of sidewall spacers 114 is provided. The sidewall spacers 114 may be composed of silicon oxide, silicon nitride, or silicon oxynitride. The gate 11 has a gate length L_{g} that may range between 0.2 micrometers and 0.6 micrometers, for example, 0.48 micrometers. The HVMOS transistor structure 2 further comprises a drain structure 12 and a source structure 14.

The HVMOS transistor structure 2 is different from the HVMOS transistor structure 1 of FIG. 1 in that the N⁺ drain contact region 122 is disposed adjacent to an edge of a salicide block (SAB) layer 202 and is therefore farther from the edge of the gate 11. The SAB layer covers the sidewall spacer 114 adjacent to the drain structure 12 and may extend to a top surface of the gate 11. No LDD is provided within the N type drift region 104 underneath the sidewall spacer 114 according to the embodiment.

Although the NMOS transistors are shown for illustration purposes, it is to be understood that in some circumstances the present invention may be suited for PMOS transistors in high-voltage applications.

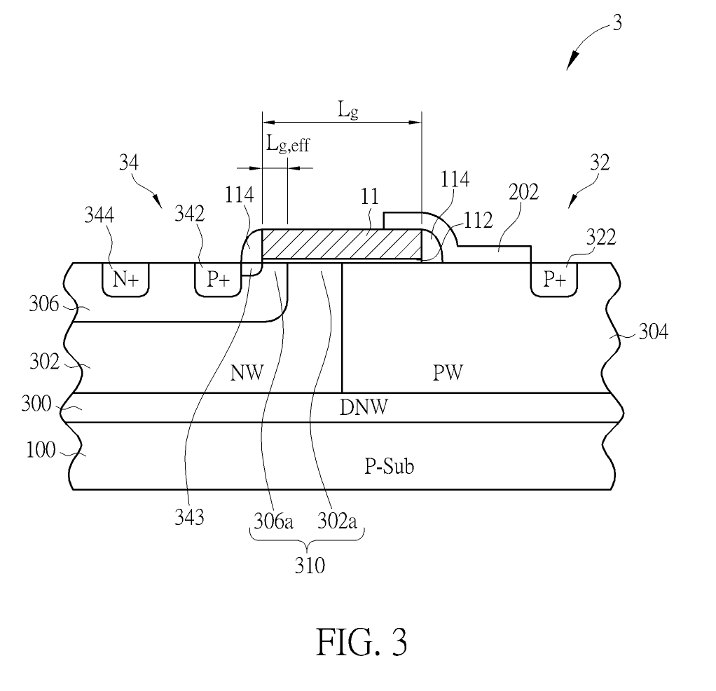

FIG. 3 is a schematic sectional view diagram showing an HVMOS transistor structure according to yet another embodiment of the invention. As shown in FIG. 3, the HVMOS transistor structure 3 comprises a semiconductor substrate 100 such as a P type silicon substrate. A gate 11 is disposed on a major surface of semiconductor substrate 100. The gate 11 may comprise at least one conductive layer such as doped polysilicon, metal, or metal silicide. A gate dielectric layer 112 such as a silicon dioxide layer may be disposed between the gate 11 and the semiconductor substrate 100. On the opposite sidewalls of the gate 11, a pair of sidewall spacers 114 is provided. The sidewall spacers 114 may be composed of silicon oxide, silicon nitride, or silicon oxynitride. The gate 11 has a gate length L_{g} that may range between 0.2 micrometers and 0.6 micrometers, for example, 0.48 micrometers.

The HVMOS transistor structure 3 further comprises a drain structure 32 in the semiconductor substrate 100. According to the embodiment, the drain structure 32 comprises a P type drift region 304 or P well (PW). The P type drift region 304 extends below the gate 11 to partially overlap with the gate 11. The drain structure 32 further comprises a P⁺ contact region 322 formed in the P type drift region 304. The P⁺ drain contact region 322 is disposed adjacent to an edge of the one of the sidewall spacers 114. It is noteworthy that no LDD is provided within the P type drift region 304 underneath the sidewall spacer 114 according to the embodiment.

An N well (NW) 302 is provided in the semiconductor substrate 100 and is situated adjacent to the P type drift region 304. According to the embodiment, the N well 302 has a first doping concentration. For example, the first doping concentration may range between 1e15 atoms/com³ and 1e16 atoms/cm³. The N well 302 partially overlaps with the gate 11. A deep N well (DNW) 300 is provided in the semiconductor substrate 100 and is situated underneath the N well 302 and the P well 304.

The HVMOS transistor structure 3 further comprises a source structure 34 in the semiconductor substrate 100. According to the embodiment, the source structure 34 comprises a shallow N well 306 in the N well 302. According to the embodiment, the shallow N well 306 has a second doping concentration. For example, the second doping concentration may range between 1e15 atoms/com³ and 5e16 atoms/cm³. According to the embodiment, the second doping concentration is higher than the first doping concentration. According to the embodiment, the shallow N well 306 also partially overlaps with the gate 11. The overlapping region 306a of the shallow N well 306 and the overlapping region 302a of the N well 302 constitute a channel region 310.

The source structure 34 further comprises a P⁺ source contact region 342 formed in the shallow N well 306. Likewise, the P⁺ source contact region 342 is disposed adjacent to an edge of the one of the sidewall spacers 114. A P type lightly doped drain (PLDD) region 343 is provided directly underneath the spacer 114 and is merged with the P⁺ source contact region 342. Further, an N⁺ well pick-up region 344 may be formed within the shallow N well 306.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high-voltage metal-oxide-semiconductor (HVMOS) transistor device, comprising:
a semiconductor substrate having a first conductivity type;
a gate overlying the semiconductor substrate;
a gate dielectric layer between the gate and the semiconductor substrate;
a sidewall spacer on each sidewall of the gate;
a drain structure in the semiconductor substrate on one side of the gate, wherein the drain structure comprises a drift region of a second conductivity type extending below the gate to partially overlap with the gate, and a drain contact region of the second conductivity type in the drift region;
an ion well of the first conductivity type in the semiconductor substrate and being situated adjacent to the drift region, wherein the ion well has a first doping concentration;
a source structure in the semiconductor substrate on the other side of the gate opposite to the drain structure, wherein the source structure comprises a shallow ion well of the first conductivity type in the ion well, a source contact region of the second conductivity type in the shallow ion well, and a lightly doped drain (LDD) region within the shallow ion well and directly underneath the spacer, and wherein the shallow ion well extends below the gate to partially overlap with the gate and has a second doping concentration, wherein the second doping concentration is higher than the first doping concentration; and
a channel region substantially consisting of an overlapping region between the shallow ion well and the gate, and an overlapping region between the ion well and the gate.

2. The HVMOS transistor device according to claim 1 wherein the drain contact region is disposed adjacent to an edge of the sidewall spacer.

3. The HVMOS transistor device according to claim 1 wherein no lightly doped drain (LDD) is provided within the drift region underneath the sidewall spacer.

4. The HVMOS transistor device according to claim 1 wherein the first doping concentration may range between 1e15 atoms/com³ and 1e16 atoms/cm³.

5. The HVMOS transistor device according to claim 4 wherein the second doping concentration may range between 1e15 atoms/com³ and 5e16 atoms/cm³.

6. The HVMOS transistor device according to claim 1 further comprising a well pick-up region within the shallow P well.

7. The HVMOS transistor device according to claim 1 wherein the gate comprises at least one conductive layer.

8. The HVMOS transistor device according to claim 1 wherein the at least one conductive layer comprises doped polysilicon, metal, or metal silicide.

9. The HVMOS transistor device according to claim 1 further comprising a salicide block (SAB) layer and wherein the drain contact region is disposed adjacent to an edge of the SAB layer.

10. The HVMOS transistor device according to claim 9 wherein the SAB layer covers the sidewall spacer adjacent to the drain structure and extends to a top surface of the gate.

11. The HVMOS transistor device according to claim 1 wherein the first conductivity type is P type and the second conductivity type is N type.

12. A high-voltage metal-oxide-semiconductor (HVMOS) transistor device, comprising:
a semiconductor substrate having a first conductivity type;
a gate overlying the semiconductor substrate;
a gate dielectric layer between the gate and the semiconductor substrate;
a sidewall spacer on each sidewall of the gate;
a drain structure in the semiconductor substrate on one side of the gate;
an ion well of the first conductivity type in the semiconductor substrate;
a source structure in the semiconductor substrate being space apart from the drain structure; and
a channel region between the drain structure and the source structure, wherein the channel region substantially consisting of two gate-overlapping regions of the first conductivity type having doping concentrations different from each other.

13. The HVMOS transistor device according to claim 12 wherein the drain structure comprises a drift region of a second conductivity type extending below the gate to partially overlap with the gate, and a drain contact region of the second conductivity type in the drift region.

14. The HVMOS transistor device according to claim 13 wherein an ion well is situated adjacent to the drift region, wherein the ion well has a first doping concentration.

15. The HVMOS transistor device according to claim 14 wherein the source structure comprises a shallow ion well of the first conductivity type in the ion well, a source contact region of the second conductivity type in the shallow ion well, a lightly doped drain (LDD) region within the shallow ion well and directly underneath the spacer, wherein the shallow ion well extends below the gate to partially overlap with the gate and has a second doping concentration, wherein the second doping concentration is higher than the first doping concentration.

16. The HVMOS transistor device according to claim 14 wherein the first doping concentration may range between 1e15 atoms/com³ and 1e16 atoms/cm³.

17. The HVMOS transistor device according to claim 15 wherein the second doping concentration may range between 1e15 atoms/com³ and 5e16 atoms/cm³.

18. The HVMOS transistor device according to claim 12 further comprising a well pick-up region within the shallow P well.

19. The HVMOS transistor device according to claim 12 wherein the gate comprises at least one conductive layer.

20. The HVMOS transistor device according to claim 19 wherein the at least one conductive layer comprises doped polysilicon, metal, or metal silicide.

21. The HVMOS transistor device according to claim 12 further comprising a salicide block (SAB) layer and wherein the drain contact region is disposed adjacent to an edge of the SAB layer.

22. The HVMOS transistor device according to claim 21 wherein the SAB layer covers the sidewall spacer adjacent to the drain structure and extends to a top surface of the gate.

23. The HVMOS transistor device according to claim 13 wherein the first conductivity type is P type and the second conductivity type is N type.
